(19) United States
(12) Patent Application Publication
(10) Pub. No.: US 2002/0089030 A1
(43) Pub. Date: Jul. 11, 2002

(54) Semiconductor substrate with functional circuit structures and dummy structures

(76) Inventor: Sabine Kling, Munchen (DE)

Correspondence Address: LERNER AND GREENBERG, P.A., PATENT ATTORNEY AND ATTORNEY AT LAW, Post Office Box 2480, Hollywood, FL, 33022-2480, US

(21) Appl. No.: 10/001,174

(22) Filed: Nov. 2, 2001

(30) Foreign Application Priority Data
Nov. 3, 2000 (DE) 100 54 566.1

(51) Int. Cl. H01L 29/00

(52) U.S. Cl. 257/499; 257/505; 257/544; 257/550

(57) ABSTRACT

In a semiconductor substrate, functional circuit structures and dummy structures are bounded by an insulation well that includes a buried diffusion region and a peripherally encompassing depth diffusion. A peripheral contact diffusion is additionally provided within a surface region defined by the depth diffusion.

### BACKGROUND OF THE INVENTION

Field of the Invention

The invention lies in the semiconductor technology field and relates, more specifically, to a semiconductor substrate with functional circuit structures and dummy structures.

Integrated circuits often have so-called dummy structures as well as functional circuit structures. Dummy structures are provided in particular when very small functional circuit structures are arranged regularly, the dummy structures serving to protect the functional circuit structures situated at the edge of such an arrangement against edge effects. Edge effects are understood here to be deviations in the functional properties of functional circuit structures located at the edge of a regular arrangement, which deviations arise by virtue of the fact that, during fabrication with the aid of a lithography process, the diffraction patterns in the inner part of such a configuration differ considerably from those at the edge of such a configuration.

The functional circuit structures are usually provided within an insulation well in order that the active regions of the circuit structures are electrically isolated from the substrate, thereby preventing short-circuiting of the functional regions via the substrate material. The insulation well usually comprises a buried layer and a closed depth diffusion which extends into the semiconductor substrate as far as the buried layer. The buried layer and also the depth diffusion have a conductivity type which differs from the conductivity type of the substrate. As a result, a diode structure is formed between the insulation well and the semiconductor substrate and is preferably operated in the reverse direction during operation of the circuit structure.

Since, from the active circuit structures within the insulation well, a considerable quantity of charge carriers can pass into the insulation well structure, it is necessary to avoid the situation wherein the insulation well assumes an unfavorable voltage potential of the insulation effect, as a result of which the blocking effect relative to the semiconductor substrate might then be cancelled.

For this reason, it is necessary that the insulation well structure can be held reliably at a specific potential, so that the functional circuit structures are always insulated from the semiconductor substrate.

### SUMMARY OF THE INVENTION

It is accordingly an object of the invention to provide a semiconductor configuration with functional circuit structures and dummy structures, which overcomes the above-mentioned disadvantages of the heretofore-known devices and methods of this general type and which allows adjusting and setting a potential of an insulation well.

With the foregoing and other objects in view there is provided, in accordance with the invention, a semiconductor configuration, comprising:

a substrate formed with an insulation well;

functional circuit structures and dummy structures lying within a region defined by the insulation well;

the insulation well including a buried diffusion region and a depth diffusion encompassing the functional circuit structures and the dummy structures and having a surface region; and

and a peripheral contact-connection diffusion formed in the surface region defined by the depth diffusion and extending around the functional circuit structures and the dummy structures.

In other words, the invention provides a semiconductor substrate with functional circuit structures and dummy structures, the functional circuit structures and the dummy structures lying within a region defined by an insulation well. The insulation well is formed by a buried layer and a depth diffusion enclosing the dummy structures and the functional circuit structures. The insulation well is furthermore provided with a peripheral contact-connection diffusion which extends around the dummy structures and the functional circuit structures within a surface region defined by the depth diffusion.

What is achieved in this way is that the insulation well can be reliably contact-connected via the contact-connection diffusion, with the result that charge carriers can flow into and from the insulation well via the smallest possible contact-connection resistance. By virtue of the fact that the contact-connection diffusion is peripheral, a relatively large interface is created between contact-connection diffusion and depth diffusion zone, said interface enabling low-resistance exchange of charge carriers.

The invention furthermore has the advantage that the contact-connection diffusion around the functional circuit structures acts in a similar manner to the dummy structures, with the result that dummy structures can be obviated. In this way, it is possible to provide a larger semiconductor surface for functional circuit structures, thereby increasing the integration density of the integrated circuits.

In accordance with an added feature of the invention, the contact-connection diffusion is contacted in a contact region. This further advantageous embodiment provides for the contact-connection diffusion to be contact-connected by at least one contact region. The advantage of this is that a low-resistance connection to the contact-connection diffusion is created via the contact region, as a result of which charge carriers can flow in or out and it is thus possible to hold the insulation well at a defined potential.

In accordance with an additional feature of the invention, the functional circuit structures are disposed in an array having an edge region, the dummy structures are disposed in the edge region, and the contact-connection diffusion encloses the dummy structures and the circuit structures. In this further preferred embodiment the functional circuit structures are arranged regularly in an array field and the dummy structures are provided at at least one edge region of the array. What is advantageously achieved as a result is that the functional circuit structures have essentially identical electrical functional properties. This is supported by the peripheral contact-connection diffusion, which acts similarly to a dummy structure.

In accordance with a concomitant feature of the invention, the functional circuit structures are memory cells.

Other features which are considered as characteristic for the invention are set forth in the appended claims.

Although the invention is illustrated and described herein as embodied in a semiconductor substrate with functional circuit structures and dummy structures, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a sectional view of a semiconductor structure according to the invention with an encompassing peripheral contact-connection diffusion; and

FIG. 2 is a plan view onto the semiconductor structure shown in FIG. 1.

### DESCRIPTION OF THE PREFERRED EMBODIMENTS

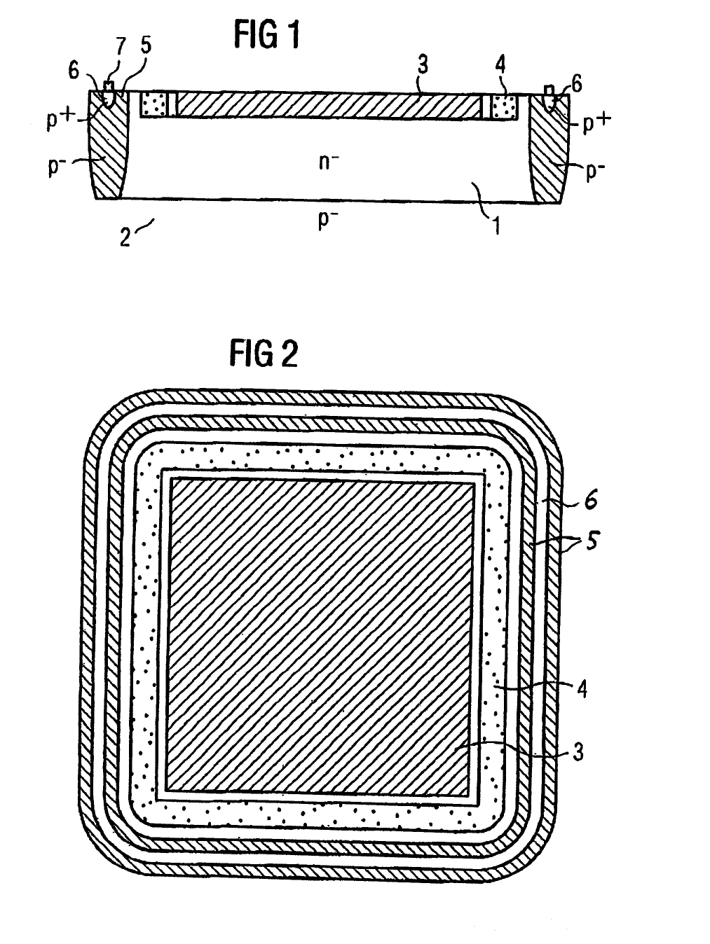

The orders of magnitude illustrated in the figures are not to scale. In particular, the vertical dimensions are greatly enlarged in order to enable a clearer illustration. Referring now to the figures of the drawing in detail and first, particularly, to FIG. 1 thereof, there is shown a semiconductor substrate with a weakly n-doped layer wherein functional circuit structures 3 and dummy structures 4 are formed. The functional circuit structures 3 and the dummy structures 4 are enclosed by an insulation well 1, which comprises a buried diffusion region 2 and a depth diffusion 5 enclosing the functional circuit structures and the dummy structures. The buried diffusion region 2 and the depth diffusion 5 are p-doped in each case, the peripheral depth diffusion extending right into the buried diffusion region 2, with the result that the insulation well 1 is completely isolated from the outer region of the semiconductor substrate.

The isolation is effected by the resulting diode structure between insulation well interior and insulation well being operated in the reverse direction. This is achieved by the depth diffusion 5 and, with it, the deep diffusion region being held at a defined potential, preferably a potential that is less than or equal to that of the n-doped region of the insulation well 1.

The insulation well 1 is contact-connected by means of a contact-connection diffusion 6, which is p⁺ doped. The contact-connection diffusion 6 lies completely within the depth diffusion 5 and completely encloses the functional circuit structures 3 and the dummy structures 4. The high p⁺-type diffusion of the contact-connection diffusion 6 enables low-resistance contact connection at a contact region with the aid of a contact metalization layer 7.

The functional circuit structures 3 may, for example, be arranged regularly in an array and the dummy structures 4 form an edge region of the array. In the edge region, the dummy structures 4 are designed essentially identically to the functional circuit structures 3. The result of this layout is that the functional circuit structures 3 at the edge of the array have essentially the same electrical properties as the functional circuit structures 3 in the inner part of the array. If a depth diffusion 5 is provided around the dummy structures 4 and the functional circuit structures 3, it is possible to reduce the number of dummy structures 4.

In particular, as can be seen from FIG. 2, the elongate arrangement of the contact-connection diffusion 6 has the effect that the functional circuit structures 3 situated at the edge of the array do not differ in their electrical properties from those in the inner part of the array.

The peripheral contact-connection diffusion makes it possible, on the one hand, to fabricate a low-resistance electrical connection to the insulation well 1 and, on the other hand, to use this structure to reduce the required dummy structures 4, without having to accept disadvantages in the electrical properties of the functional circuit structures located at the edge of the array.

It goes without saying that it is obvious to the person skilled in the art that the insulation well can also be formed with an n-doped material instead of with a p-doped material, the insulation well interior then preferably being composed of a p-doped material.

Furthermore, it is expedient to provide the contact metalization layer 7 at specific intervals on the peripheral contact-connection diffusion 6. In each case, the same potential is applied to the connection points of the contact metalization layer 7. In this way, it is possible to further reduce the resistance when contact-connecting the insulation well 1.

I claim:

1. A semiconductor configuration, comprising:
a substrate formed with an insulation well;
functional circuit structures and dummy structures within a region defined by said insulation well;
said insulation well including a buried diffusion region and a depth diffusion encompassing said functional circuit structures and said dummy structures and having a surface region; and
a peripheral contact-connection diffusion formed in said surface region defined by said depth diffusion and extending around said functional circuit structures and said dummy structures.

2. The semiconductor configuration according to claim 1, which further comprises a contact structure connected to said contact-connection diffusion in a contact region.

3. The semiconductor configuration according to claim 1, wherein said functional circuit structures are disposed in a field having an edge region, said dummy structures are disposed in said edge region, and said contact-connection diffusion encloses said dummy structures and said circuit structures.

4. The semiconductor configuration according to claim 1, wherein said functional circuit structures are memory cells.
